(19) United States
(12) Patent Application Publication
(10) Pub. No.: US 2019/0265277 A1
(43) Pub. Date: Aug. 29, 2019

(54) CIRCUIT BOARD FOR TESTING AND METHOD OF OPERATING THE SAME

(71) Applicant: SV PROBE PTE. LTD., Singapore (SG)

(72) Inventors: Sheng-Yu Tseng, Hsinchu Country (TW); Cheng-Yi Wu, Kaohsiung City (TW)

(21) Appl. No.: 16/154,797

(22) Filed: Oct. 9, 2018

(30) Foreign Application Priority Data
Feb. 26, 2018 (TW) 107106366

(51) Int. Cl. G01R 1/20; H05K 1/18; G01R 1/067; G01R 1/073

(52) U.S. Cl. CPC G01R 1/20; H05K 1/181; H05K 2201/10053; G01R 1/07342; G01R 1/06772

(57) ABSTRACT

A circuit board for testing and a method of operating the same are provided. A relay is installed on a body of a circuit board having a probe. At least one external conductive line is arranged between the probe and the relay. During high-frequency signal testing, a transmission route is to transmit high-frequency signals to a test machine by means of the external conductive line, but is not to transmit high-frequency signals to a test machine by means of the relay. Accordingly, the limitation of the bandwidth condition of the relay can be avoided.

### CROSS-REFERENCE RELATED APPLICATION

This application claims the priority of Taiwanese patent application No. 107106366, filed on Feb. 26, 2018, which is incorporated herewith by reference.

### BACKGROUND

### 1. Technical Field

The present disclosure relates to electrical testing equipment, and, more particularly, to a circuit board for electrical testing.

### 2. Description of Related Art

A traditional probe card is typically connected to signal contacts of a wafer through its probes for testing and determining whether the circuits of the wafer are normal.

With the advancement of digital technology, the processing speeds and the signal transmissions per second of wafers under test also keep increasing day by day. As a result, the frequency of test signals generated by a traditional probe card can no longer satisfy signal transmissions of high-frequency test signals required for the wafers under test. Therefore, relays provided on probe cards have been used for high-frequency testing. The types of the relays may include, for example, electro-mechanical relay, reed relay, and semiconductor relay; in addition, the semiconductor relay is the smallest and the lowest in cost.

As shown in FIG. 1, a substrate 10 of a conventional probe card 1 is provided with at least one semiconductor relay 11. The semiconductor relay 11 is controlled by a control circuit 13 to enable a low-frequency test signal route L1 or a high-frequency test signal route L2. The low-frequency test signals or the high-frequency test signals are then transmitted through respective wires 12 on the substrate 10.

However, during high-frequency testing of the conventional probe card 1, the bandwidth of the relay 11 is too small (up to 4 GHz (8 Gbps)), resulting in difficult transmissions of the high-frequency test signals, and thereby causing a test machine to easily produce erroneous test results.

In addition, since the high-frequency test signal route L2 for transmitting the high-frequency test signals is rather long (composed of a probe 100 of the substrate 10, the relay 11, and the wire 12), larger impedance would be created on the high-frequency test signal route L2, so as to increase the loss of the wire 12, and thereby causing the test results of the test machine to easily produce erroneous test results.

Therefore, there is a need for a solution that addresses the aforementioned issues in the prior art.

### SUMMARY

In view of the aforementioned shortcomings of the prior art, the present disclosure provides a circuit board for testing, including: a circuit board body provided with at least one probe; a relay disposed on the circuit board body and including an input end electrically connected to the probe and an output end, wherein a first switch is disposed between the input end and the output end; a wire arranged on the circuit board body and electrically connected with the output end of the relay and connected with the first switch correspondingly; and an external conductive line arranged between the probe and the input end of the relay and electrically connected with the probe.

The present disclosure further provides a method of operating the circuit board, including the steps of: providing the circuit board as described above; during low-frequency signal testing, electrically connecting the probe with the wire through the input end of the relay, the first switch, and the output end of the relay; and during high-frequency signal testing, electrically connecting the probe with the external conductive line.

In an embodiment, a second switch is further arranged between the input end and the output end of the relay, wherein the wire is not connected with the second switch. In another embodiment, during the low-frequency signal testing, the first switch is turned on and the second switch is turned off. In yet another embodiment, during the high-frequency signal testing, the first switch is turned off and the second switch is turned on.

In an embodiment, the external conductive line is arranged between the probe and the input end of the relay by soldering.

As can be understood from the above, the circuit board for testing and the method of operating the same according to the present disclosure make use of the external conductive line, such that the transmission route during the high-frequency signal testing passes through the external conductive line instead of the relay. Accordingly, the limitation of the bandwidth condition of the relay can be avoided. Compared to the prior art, the circuit board for testing according to the present disclosure enables the effective transmission of high-frequency test signals by using the external conductive line to prevent erroneous test results from being generated at the test machine.

Moreover, since the transmission route for transmitting test signals is shortened, the impedance on the transmission route is reduced, such that the loss of the circuits is decreased and a successful transmission of high-frequency test signals is enabled. Thus, compared to the prior art, the present disclosure eliminates erroneous test results arising from large circuit impedance at the test machine.

### BRIEF DESCRIPTION OF THE DRAWINGS

FIG. 1 is a schematic diagram depicting a traditional probe card; and

FIGS. 2 and 3 are schematic diagrams depicting a circuit board for testing in accordance with the present disclosure.

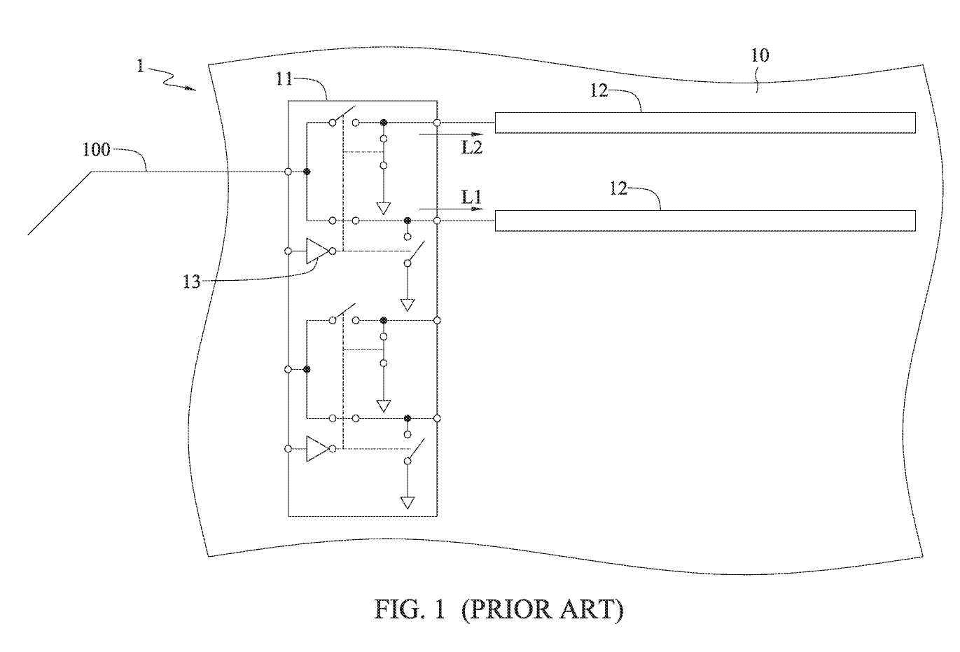

### DETAILED DESCRIPTION OF THE EMBODIMENTS

The technical content of present disclosure is described by the following specific embodiments. One of ordinary skill in the art can readily understand the advantages and effects of the present disclosure upon reading the disclosure of this specification. The present disclosure may also be practiced or applied with other different implementations. Based on different contexts and applications, the various details in this specification can be modified and changed without departing from the spirit of the present disclosure.

It should be noted that the structures, ratios, sizes shown in the drawings appended to this specification are to be construed in conjunction with the disclosure of this specification in order to facilitate understanding of those skilled in the art. They are not meant, in any ways, to limit the implementations of the present disclosure, and therefore have no substantial technical meaning. Without affecting the effects created and objectives achieved by the present disclosure, any modifications, changes or adjustments to the structures, ratio relationships or sizes, are to be construed as fall within the range covered by the technical contents disclosed herein. Meanwhile, terms, such as “above”, “one”, “a”, “an”, and the like, are for illustrative purposes only, and are not meant to limit the range implementable by the present disclosure. Any changes or adjustments made to their relative relationships, without modifying the substantial technical contents, are also to be construed as within the range implementable by the present disclosure.

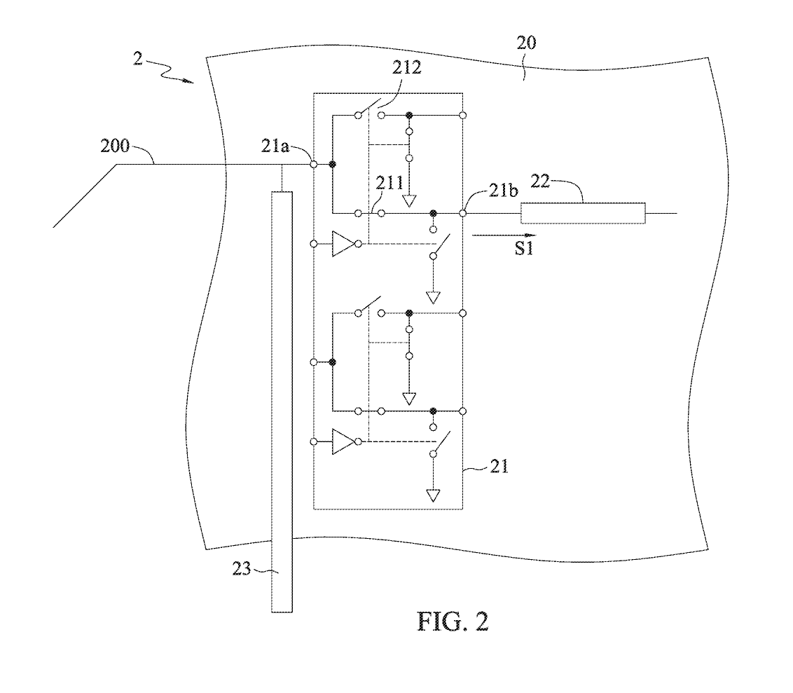

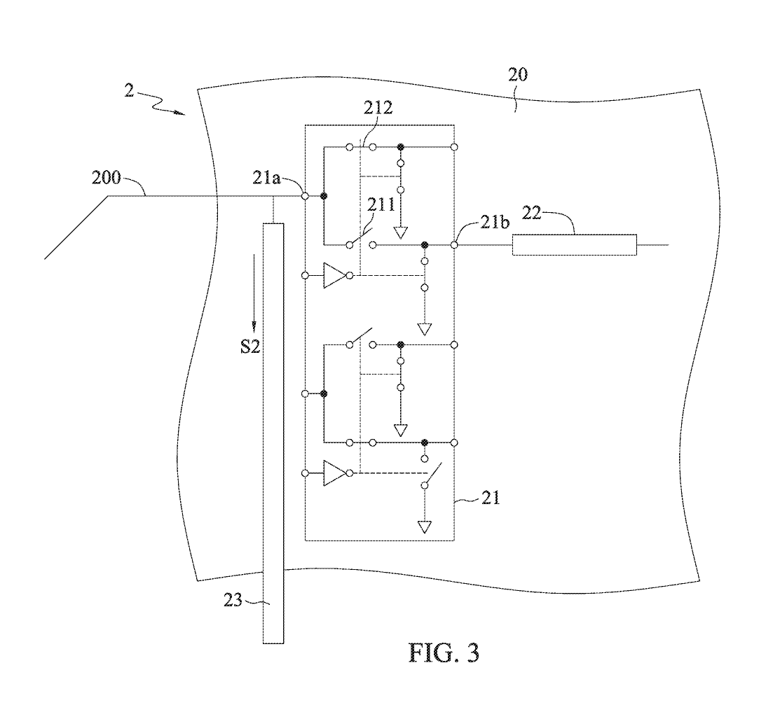

Referring to FIGS. 2 and 3, schematic diagrams depicting a circuit board 2 for testing in accordance with the present disclosure are shown. The circuit board 2 includes a circuit board body 20 with at least one probe 200, at least one relay 21, at least one wire 22, and at least one external conductive line 23.

In an embodiment, the circuit board 2 is a circuit board to be used by a test machine, such as a probe card used for testing wafers/chips or a load board for testing semiconductor packages.

The circuit board body 20 may have a general structure or a customized structure. There are numerous types of structures possible for the circuit board body 20, and the present disclosure is not particularly limited to a specific type.

The relay 21 is provided on the circuit board body 20 with at least an input end 21a and at least an output end 21b. A first switch 211 and a second switch 212 are arranged between the input end 21a and the output end 21b. A probe 200 is electrically connected to the input end 21a.

In an embodiment, the relay 21 is semiconductor relay, such as analog ADG 936 model with a bandwidth of about 4 GHz (8 Gbps).

The wire 22 is provided on the circuit board body 20 outside the relay 21, and is electrically connected with the output end 21b to be in turn connected with the first switch 211 but not with the second switch 212.

The external conductive line 23 is provided between the probe 200 and the input end 21a of the relay 21.

In an embodiment, the external conductive line 23 is a transmission component such as a lead, and is arranged between the probe 200 and the input end 21a by soldering. The external conductive line 23 may be selected based on the bandwidth requirement, such as a wire having a bandwidth greater than 4 GHz (8 Gbps).

Therefore, the method of operating the circuit board for testing 2 for low-frequency signal testing (as shown in FIG. 2) includes the step of turning on the first switch 211 and turning off the second switch 212, such that the probe 200 is electrically connected with the wire 22 via the input end 21a of the relay 21, the first switch 211, and the output end 21b. In an embodiment, a transmission route for low-frequency test signals S1 transmits signals from a wafer under test (not shown) to the test machine (not shown) through the probe 200, the input end 21a of the relay 21, the first switch 211, the output end 21b.

On the contrary, during high-frequency signal testing (as shown in FIG. 3), the method includes the step of turning off the first switch 211 and turning on the second switch 212, such that the probe 200 is electrically connected with the external conductive line 23. In other words, a transmission route for high-frequency test signals S2 transmits signals from the wafer under test (not shown) to the test machine (not shown) through the probe 200 and the external conductive line 23.

In summary, the circuit board 2 and the method of operating the same according to the present disclosure make use of the external conductive line 23, such that the transmission route S2 during high-frequency signal testing passes through the external conductive line 23 instead of the relay 21. Accordingly, the limitation of the bandwidth condition of the relay 21 can be avoided. Compared to the prior art, the circuit board 2 according to the present disclosure enables the effective transmission of high-frequency test signals using the external conductive line 23 to prevent erroneous test results from being generated at the test machine.

Moreover, since the transmission route S2 for transmitting test signals is shortened (signals only have to pass through the probe 200 and the external conductive line 23 before arriving at the test machine), the impedance on the transmission route S2 is reduced, such that the loss of the circuits is decreased and a successful transmission of high-frequency test signals is enabled. Thus, compared to the prior art, the present disclosure eliminates erroneous test results arising from large circuit impedance at the test machine.

The above embodiments are only used to illustrate the principles of the present disclosure, and should not be construed as to limit the present disclosure in any way. The above embodiments can be modified by those with ordinary skill in the art without departing from the scope of the present disclosure as defined in the following appended claims.

What is claimed is:

1. A circuit board for testing, comprising:
a circuit board body provided with at least one probe;
a relay disposed on the circuit board body and including an input end and an output end with a first switch arranged between the input end and the output end, wherein the input end of the relay is electrically connected to the probe;
a wire arranged on the circuit board body and electrically connected with the output end of the relay and connected with the first switch correspondingly; and
an external conductive line arranged between the probe and the input end of the relay and electrically connected with the probe.

2. The circuit board of claim 1, further comprising a second switch arranged between the input end and the output end of the relay.

3. The circuit board of claim 2, wherein the wire is free from being connected with the second switch.

4. The circuit board of claim 2, wherein, when the first switch is turned on and the second switch is turned off, the probe is electrically connected with the wire through the input end of the relay, the first switch, and the output end of the relay to transmit a low-frequency test signal.

5. The circuit board of claim 2, wherein, when the first switch is turned off and the second switch is turned on, the probe is electrically connected with the external conductive line to transmit a high-frequency test signal.

6. The circuit board of claim 1, wherein the external conductive line is arranged between the probe and the input end of the relay by soldering.

7. A method of operating a circuit board for testing, comprising:
providing the circuit board of claim 1;
during low-frequency signal testing, electrically connecting the probe with the wire through the input end of the relay, the first switch, and the output end of the relay; and
during high-frequency signal testing, electrically connecting the probe with the external conductive line.

8. The method of claim 7, wherein the circuit board further comprises a second switch arranged between the input end and the output end of the relay.

9. The method of claim 8, wherein the wire is free from being connected with the second switch.

10. The method of claim 8, wherein during the low-frequency signal testing, the first switch is turned on and the second switch is turned off.

11. The method of claim 8, wherein during the high-frequency signal testing, the first switch is turned off and the second switch is turned on.

12. The method of claim 7, wherein the external conductive line is arranged between the probe and the input end of the relay by soldering.
